(19) United States
(12) Patent Application Publication
(10) Pub. No.: US 2021/0312332 A1
(43) Pub. Date: Oct. 7, 2021

(54) METHOD FOR SIMULATING A COUPLED GEOLOGICAL AND DRILLING ENVIRONMENT FOR TRAINING A FUNCTION APPROXIMATING AGENT

(71) Applicant: SHELL OIL COMPANY, HOUSTON, TX (US)

(72) Inventors: Neilkunal PANCHAL, Houston, TX (US); Sami Mohammed Khair SULTAN, Houston, TX (US); David THANOON, Houston, TX (US); Andres Tomas SUAREZ, Houston, TX (US); Misael Jacobo UZCATEGUI DIAZ, Houston, TX (US)

(21) Appl. No.: 17/263,961

(22) PCT Filed: Jul. 30, 2019
(86) PCT No.: PCT/US2019/044029

§ 371 Date: Jan. 28, 2021

Related U.S. Application Data
(60) Provisional application No. 62/712,490, filed on Jul. 31, 2018.

(30) Foreign Application Priority Data
Sep. 14, 2018 (EP) 18194385.3

(51) Int. Cl. G06N 20/00; E21B 47/09; E21B 7/04; G06F 30/20

(52) U.S. Cl. CPC G06N 20/00; E21B 47/09; E21B 2200/22; G06F 30/20; E21B 2200/20; E21B 7/04

(57) ABSTRACT

A method for producing a simulation environment for training a function approximating agent uses an earth model that defines boundaries between formation layers and petrophysical properties of the formation layers in a subterranean formation. A toolface input corresponding to a set of model coefficients produced by the earth model is provided to a drilling attitude model, which produces a drill bit position. The drill bit position is fed to the earth model for determining an updated set of model coefficients for a predetermined interval and a set of signals representing physical properties of the subterranean formation. The signals are provided to a sensor model to produce at least one sensor output. A reward is determined from the sensor output. The simulation environment for training the function approximating agent can be used for automating a geosteering process.

### FIELD OF THE INVENTION

The present invention relates to the field of geosteering and, in particular, to a method for producing a simulation environment for training a function approximating agent for automating geosteering.

### BACKGROUND OF THE INVENTION

In a well construction process, rock destruction is guided by a drilling assembly. The drilling assembly includes sensors and actuators for biasing the trajectory and determining the heading in addition to properties of the surrounding borehole media. The intentional guiding of a trajectory to remain within the same rock or fluid and/or along a fluid boundary such as an oil/water contact or an oil/gas contact is known as geosteering.

Geosteering may be used to keep a wellbore in a particular section of a reservoir to minimize gas or water breakthrough and maximize economic production from the well. To accomplish the objective, the borehole position, typically the drilling assembly inclination and azimuth angles, are adjusted “on the fly” to reach one or more geological targets. The adjustments are based on geological information gathered from sensors while drilling.

Conventionally, a human geosteerer at the surface monitors the drilling operation and data and instructs a human directional driller to make target line adjustments by changing a drilling parameter. A disadvantage of conventional geosteering processes is the lag time between the bottom hole assembly and the surface, for communicating data to and from the surface. The industry has made efforts to overcome this disadvantage.

For example, U.S. Pat. No. 9,273,517B2 (Schlumberger) relates to a closed-loop method for downhole geosteering calculations and adjustments to steering direction without the need for surface processing or decision-making. The method provides for autonomous downhole decisions based on feedback from on-the-fly LWD measurements. In particular, directional resistivity measurements are acquired while the bottom hole assembly is rotating and a downhole processor computes a geosteering correction based on the directional resistivity. In one embodiment, the downhole processor selects directional resistivity values from a lookup table deployed downhole on a memory chip to closely match LWD measurements. A geosteering well position corresponding to the directional resistivity value is then selected by the downhole processor from the look-up table.

U.S. Pat. No. 1,000,104B2 (Schlumberger) describes another closed-loop method using model predictive control (MPC) for controlling the direction drilling attitude. The MPC scheme incorporates a state space plant model derived from kinematic considerations relating borehole inclination and azimuth to rate of penetration, tool face angle control and drop and turn rate disturbances. The method includes receiving a demand attitude and a measured attitude. The received values are processed by MPC to obtain an attitude error for further processing into a corrective setting for a directional drilling tool. In one embodiment, the method may include a feed forward step for obtaining feed forward inclination and azimuth errors/virtual control outputs from measured borehole inclination and borehole azimuth values.

While these two patents do provide for more automation of a geosteering process and address feedback delay from measurements and sensors, they each rely on one aspect of a multi-faceted analysis conventionally conducted by a geosteerer and a directional driller. While the geosteerer and directional driller make best efforts to maintain a well plan initially determined by a drilling engineer and geologist, based on experience and data, there are inherently unknown factors in subterranean formations. Furthermore, uncertainties are compounded by the behavior of the drill tool, which has a tendency to curve and to mechanically respond to different types of rock properties and anomalies that may be encountered subsurface. As such, the degree of uncertainty increases with borehole depth and distance. Accordingly, there are often departures in actual well path, as compared with original well plan, resulting in increased cost. For example, when a drilled borehole is out of target zone 10% of the time, there can be upwards of 5% loss in production of hydrocarbons, resulting in excess costs of $250,000-$300,000 NPV/well, in addition to any drilling inefficiencies the out of target zone drilling may have caused.

There is a need for improving a geosteering process by improving the reaction time and accuracy of a drilling tool in a subterranean formation.

### SUMMARY OF THE INVENTION

According to one aspect of the present invention, there is provided a method for producing a simulation environment for training a function approximating agent, comprising the steps of: (a) providing an earth model defining boundaries between formation layers and petrophysical properties of the formation layers in a subterranean formation comprising data selected from the group consisting of seismic data, data from an offset well and combinations thereof, and producing a set of model coefficients; (b) providing a toolface input corresponding to the set of model coefficients to a drilling attitude model for determining a drilling attitude state; (c) determining a drill bit position in the subterranean formation from the drilling attitude state; (d) feeding the drill bit position to the earth model, and determining an updated set of model coefficients for a predetermined interval and a set of signals representing physical properties of the subterranean formation for the drill bit position; (e) inputting the set of signals to a sensor model for producing at least one sensor output and determining a reward from the at least one sensor output; (f) correlating the toolface input and the corresponding drilling attitude state, drill bit position, set of model coefficients, and the at least one sensor output and sensor reward in the simulation environment; and (g) repeating steps b)-f) using the updated set of model coefficients from step d) and to produce the simulation environment for training the function approximating agent.

### BRIEF DESCRIPTION OF THE DRAWINGS

The method of the present invention will be better understood by referring to the following detailed description of preferred embodiments and the drawings referenced therein, in which:

FIG. 1 is a flow diagram illustrating one embodiment of the method of the present invention;

FIG. 2 is a flow diagram of another embodiment of the present invention, illustrating an embodiment of a drilling model;

FIG. 3 is a graphical representation of the results of a first test of a simulation environment produced according to the method of the present invention;

FIG. 4 is a graphical representation of the results of a second test of a simulation environment produced according to the method of the present invention;

FIG. 5 is a graphical representation of the results of a third test of a simulation environment produced according to the method of the present invention; and

FIG. 6 is a graphical representation of the results of a fourth test of a simulation environment produced according to the method of the present invention.

### DETAILED DESCRIPTION OF THE INVENTION

The present invention provides a method for producing a simulation environment for training a function approximating agent. Once trained, the process can be applied to automating geosteering processes with faster response times to unknown and/or uncertain factors while drilling a non-vertical borehole. The method is a computer-implemented method.

By using data from the simulation environment to train a function approximating agent, the effectiveness and accuracy of the training is significantly improved. By “function approximating agent” we mean a process for finding an underlying relationship from a given finite set of input-output data. Examples of function approximating agents include neural networks, such as backpropagation-enabled processes, including deep learning, machine learning, frequency neural networks, Bayesian neural networks, Gaussian processes, polynomials, and derivative-free processes, such as annealing processes, evolutionary processes and sampling processes. Examples of function approximating agents include, without limitation, agents trained in the context of reinforcement learning, deep reinforcement learning, approximate dynamic programming, in either a model-free or a model-based method. In model-free methods, the function approximating is used to approximate a value function which is trained by methods such as value iteration, policy iteration or actor critic methods. In model-based methods, a function approximator may be used to directly approximate the model itself. It will be understood by those skilled in the art that advances in function approximating agents continue rapidly. The method of the present invention is expected to be applicable to those advances even if under a different name. Accordingly, the method of the present invention is applicable to the further advances in function approximating agents, even if not expressly named herein.

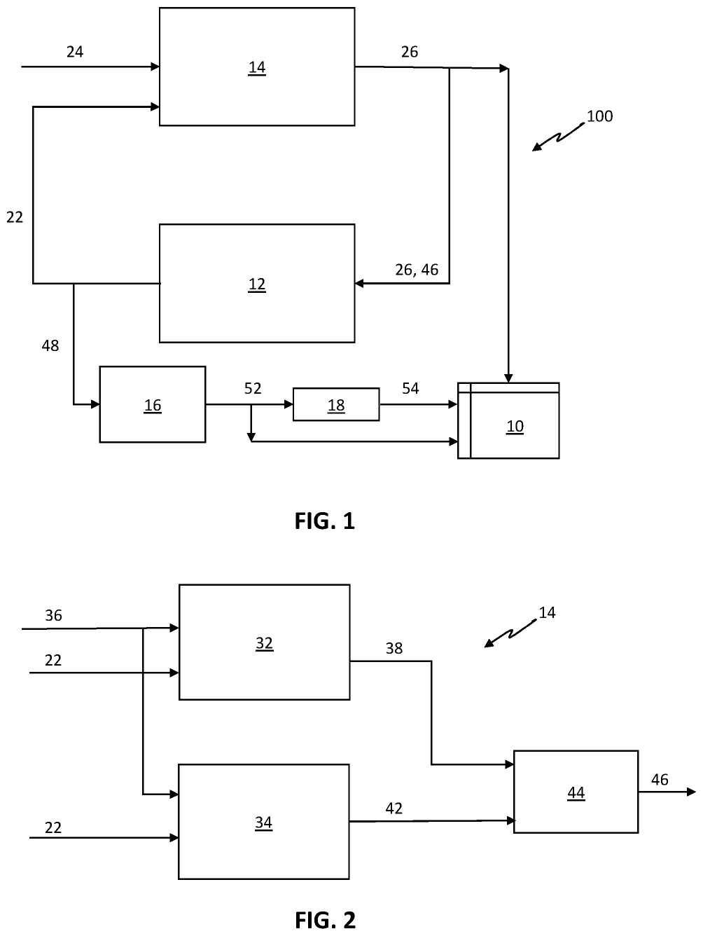

Referring now to FIG. 1, the method of the present invention 100 produces a simulation environment 10 by providing an earth model 12, a drilling attitude model 14 and a sensor model 16.

The earth model 12 defines boundaries between formation layers and petrophysical properties of the formation layers of a subterranean formation. The earth model 12 is produced from data relating to a subterranean formation, the data selected from the group consisting of seismic data, data from an offset well and combinations thereof. Preferably, the earth model 12 is a 3D model. Preferably, the earth model 12 also incorporates synthetic data. In another embodiment, the earth model 12 may be a synthetic subterranean formation. By adding synthetic data, a function approximating agent may be trained to respond to formation factors not anticipated by existing data. This improves the accuracy and responsiveness of the so-trained function approximating agent.

A set of model coefficients 22 generated by the earth model 12 are used as inputs to the drilling attitude model 14. The set of model coefficients 22 are representative of a point or volume in the earth model 12 and factor geologic position, geologic objectives, lithology, rock types, rock properties, and combinations thereof.

A toolface input 24 corresponding to the set of model coefficients 22 is also provided to the drilling attitude model 14. The drilling attitude model 14 can be represented as, for example, without limitation, a kinematic model, a dynamical system model, a finite element model, a Markov decision process, and the like. Dynamical system models aim to embody actual drilling assembly dynamics as closely as possible, encompassing parameters including, without limitation, longitudinal and lateral forces, gravity, angular steering resistance, lateral steering resistance, mass, the geometry of the assembly, and the like. Kinematic models are simplifications of dynamical models that ignore angular steering resistance, lateral steering resistance, gravity, and mass of the drill string. This simplification reduces the accuracy of the model, but also makes it more tractable.

Based on the set of model coefficients 22 and the toolface input 24, the drilling attitude model 14 produces a drilling attitude state 26.

The drilling attitude model 14 is preferably a 3D drilling attitude model. More preferably, as shown in FIG. 2, the drilling attitude model 14 is a combination of a drilling inclination model 32 and a drilling azimuth model 34. Each of the drilling inclination model 32 and the drilling azimuth model 34 may themselves be 2D or 3D.

For a given input parameter 36, such as weight-on-bit force, tool curvature, roll angle, and the like, and the set of model coefficients 22, the drilling inclination model 32 produces an inclination angle 38. And, for a given set of model coefficients 22, the drilling azimuth model 34 produces an azimuth 42. Preferably, the drilling attitude model 14 produces both an inclination angle 38 and an azimuth 42, which may be provided to the earth model 12 directly or processed by an intermediate step, for example by a processor 44, such as an integrator, to determine a drill bit position 46. The drill bit position 46 may be a true vertical depth, a relative stratigraphic depth and combinations thereof.

The drill bit position 46 is fed to earth model 12 for producing an updated set of model coefficients 22 for a predetermined interval, for example a time or length interval. Along with the set of model coefficients 22, the output of the earth model 12 is a set of signals 48 representing the properties of the subterranean formation. The properties include those properties that would typically be measured including, without limitation, natural gamma, neutron porosity, density, resistivity, water saturation, permeability, and the like.

The set of signals 48 is input to the sensor model 16 for determining a respective sensor output 52 that would have been produced for determining the set of signals 48, if measurements were being made while drilling and/or from seismic data. The set of sensor outputs 52 simulate responses from an LWD sensor, an MWD sensor, image logs, 2D seismic data, 3D seismic data and combinations thereof.

The LWD sensor may be selected from the group consisting of gamma-ray detectors, neutron density sensors, porosity sensors, sonic compressional slowness sensors, resistivity sensors, nuclear magnetic resonance, and combinations thereof.

The MWD sensor is selected from the group consisting of sensors for measuring mechanical properties, inclination, azimuth, roll angles, and combinations thereof.

A sensor reward 54 is determined by a reward function 18 for the corresponding drilling attitude state 26, drill bit position 46, set of model coefficients 22, set of signals 48 and sensor outputs 52. The sensor reward 54 is preferably a user-defined reward function along with states and actions. The sensor reward 54 is determined once the reward function 18 is evaluated with inputs of the functions from sensor outputs 52. The reward function is used to train a process including, without limitation, a deep reinforcement learning agent a dynamic programming process, a policy optimization process, and the like. Examples of dynamic programming processes include, without limitation, policy iteration processes, value iteration processes, Q-learning processes, and the like. Examples of policy optimization processes include, without limitation, policy gradient processes, derivative free operations, evolution processes, and the like.

The sensor reward 54, drilling attitude state 26, drill bit position 46, set of model coefficients 22, set of signals 48 and sensor output 52 are correlated in the simulation environment 10. Using an updated set of model coefficients 22, the method steps are repeated for the next predetermined interval. In accordance with the present invention, the steps can be repeated a number of times to produce a significant amount of data for training a function approximating agent.

The simulation environment of the present invention is useful for training a function approximating agent.

### Examples 1-4

The accuracy of the simulation environment produced in accordance with the present invention was tested by training a function approximating agent.

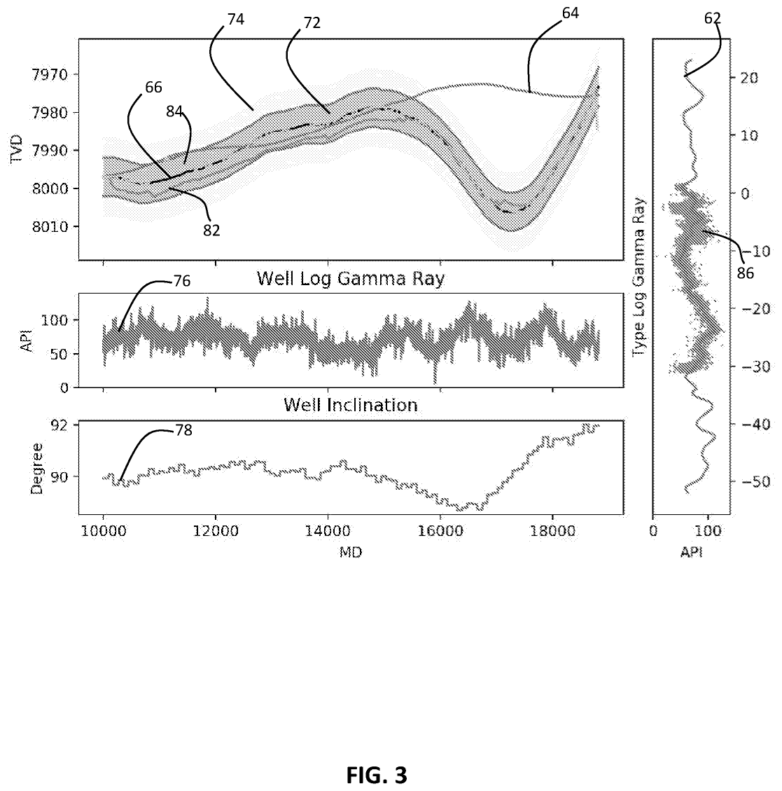

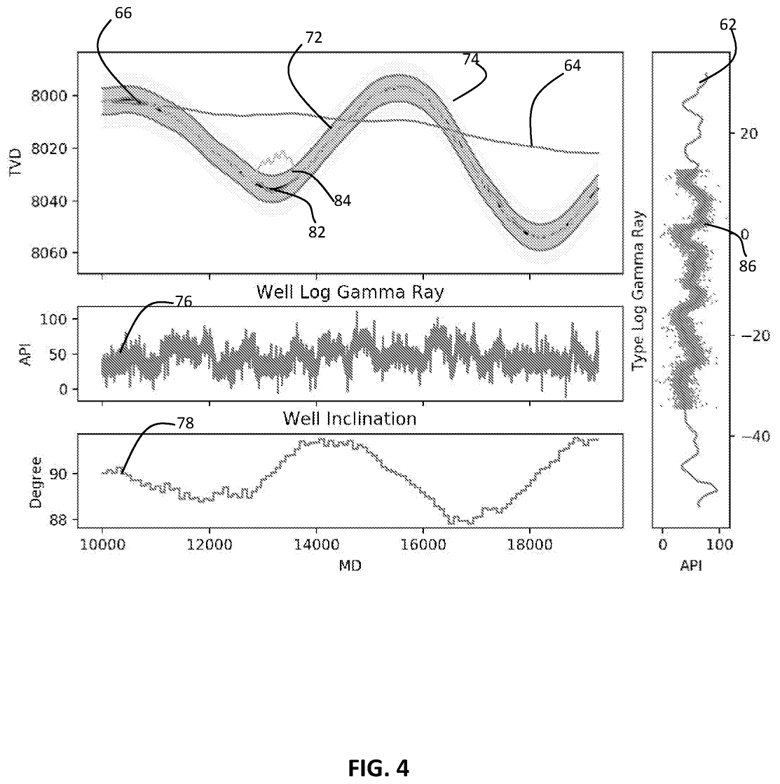

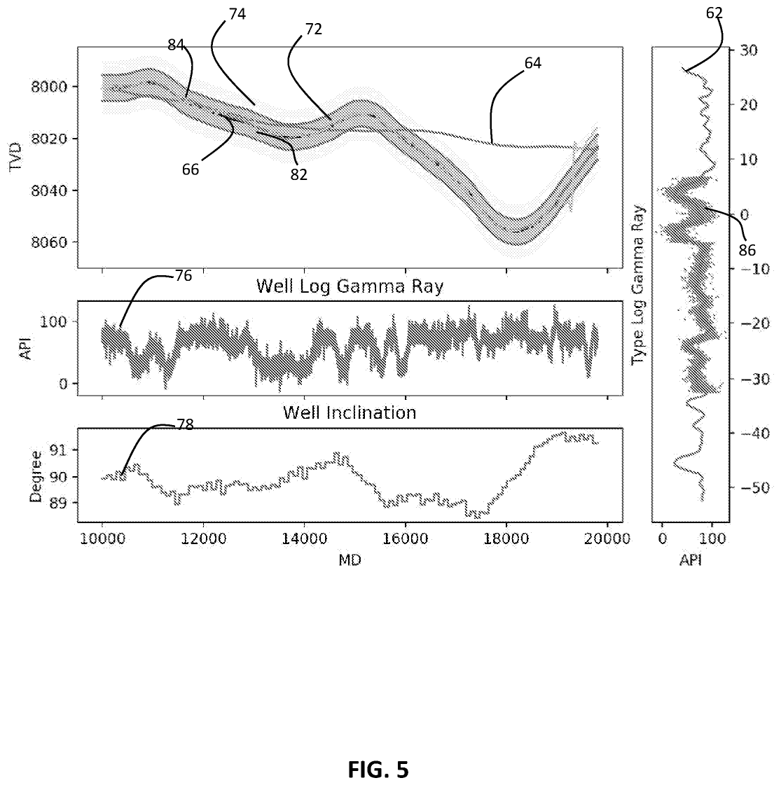

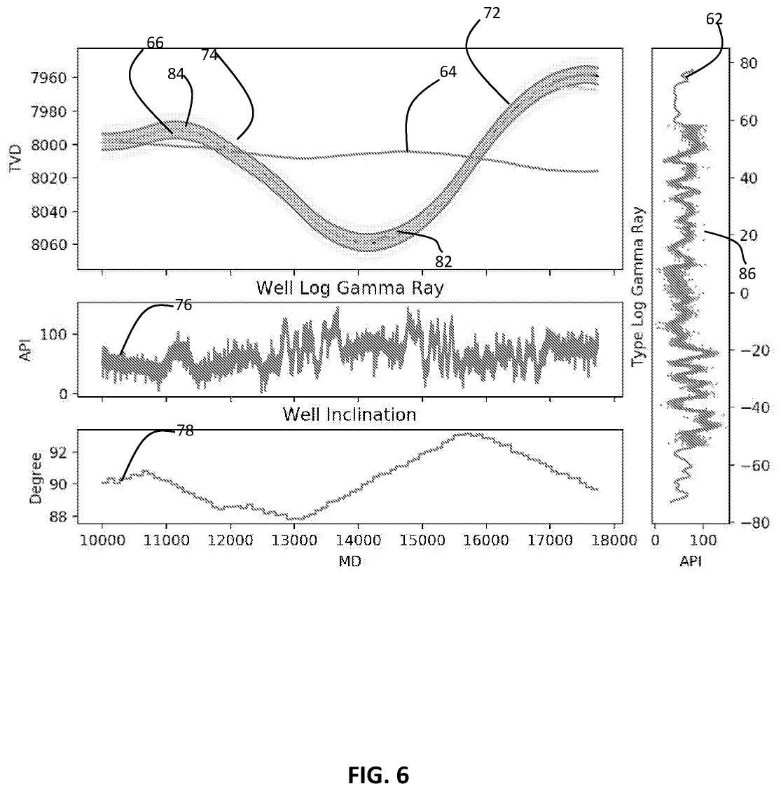

Referring now to FIGS. 3-6, a synthetic well was generated based on an actual gamma ray log. The real data is identified by a type log gamma ray plot 62. Based on the type log gamma ray plot 62, a boundary 64 representing the top of a target formation was determined and a synthetic true well path 66 was generated. Region 72 represents a 1.5-m (5-foot) error about the true well path 66, while region 74 represents a 3-m (10-foot) error about the well path 66. The goal of the test was to match the true well path 66 as best as possible.

In each of Example 1-4, the function approximating agent is described in co-pending application entitled “Process for Real Time Geological Localization with Bayesian Reinforcement Learning” filed in the USPTO on the same day as the present application, as provisional application U.S. 62/712,518 filed 31 Jul. 2018, the entirety of which is incorporated by reference herein. The Bayesian Reinforcement Learning (BRL) function approximating agent was trained by the method described herein.

Well log gamma ray data 76 was fed to the trained agent and a set of control inputs, in this case well inclination angle 78, was used to steer the well-boring along the true well path 66, according to the method described in co-pending application entitled “Process for Training a Deep Learning Process for Geological Steering Control” filed in the USPTO on the same day as the present application, as provisional application U.S. 62/712,506 filed 31 Jul. 2018, the entirety of which is incorporated by reference herein.

The well path 82 resulting from the BRL agent and the well path 84 resulting from the BRL agent with mean square error demonstrated good fit to the true well path 66. As shown in FIGS. 3-6, the fit of well paths 82 and 84 improved over time with a reward function described in the autonomous geosteering method.

While preferred embodiments of the present disclosure have been described, it should be understood that various changes, adaptations and modifications can be made therein without departing from the spirit of the invention(s) as claimed below.

1. A method for producing a simulation environment for training a function approximating agent, comprising the steps of:
a) providing an earth model defining boundaries between formation layers and petrophysical properties of the formation layers in a subterranean formation comprising data selected from the group consisting of seismic data, data from an offset well and combinations thereof, and producing a set of model coefficients;
b) providing a toolface input corresponding to the set of model coefficients to a drilling attitude model for determining a drilling attitude state;
c) determining a drill bit position in the subterranean formation from the drilling attitude state;
d) feeding the drill bit position to the earth model, and determining an updated set of model coefficients for a predetermined interval and a set of signals representing physical properties of the subterranean formation for the drill bit position;
e) inputting the set of signals to a sensor model for producing at least one sensor output and determining a sensor reward from the at least one sensor output;
f) correlating the toolface input and the corresponding drilling attitude state, drill bit position, set of model coefficients, and the at least one sensor output and sensor reward in the simulation environment; and
g) repeating steps b)-f) using the updated set of model coefficients from step d) and to produce the simulation environment for training the function approximating agent.

2. The method of claim 1, further comprising the step of training a function approximating agent using a user-defined reward function along with states and actions, wherein the user-defined reward function is selected from the group consisting of deep reinforcement learning agent, dynamic programming processes, policy optimization processes, and derivatives and combinations thereof.

3. The method of claim 1, wherein the function approximating agent trained by the simulation environment is used for automating a geosteering process.

4. The method of claim 1, wherein the toolface input is selected from the group consisting of curvature, roll angle, weight-on-bit and combinations thereof.

5. The method of claim 1, wherein the drilling attitude state is selected from the group consisting of inclination, azimuth, and combinations thereof.

6. The method of claim 1, wherein the drill bit position in a true vertical depth, a relative stratigraphic depth, and combinations thereof.

7. The method of claim 1, wherein the subterranean formation is a synthetic subterranean formation.

8. The method of claim 1, wherein the earth model further comprises synthetic data.

9. The method of claim 1, wherein the sensor outputs simulate responses from an LWD sensor, an MWD sensor, image logs, 2D seismic data, 3D seismic data and combinations thereof.

10. The method of claim 9, wherein the LWD sensor is selected from the group consisting of gamma-ray detectors, neutron density sensors, porosity sensors, sonic compressional slowness sensors, resistivity sensors, nuclear magnetic resonance, and combinations thereof.

11. The method of claim 10, wherein the MWD sensor is selected from the group consisting of sensors for measuring mechanical properties, inclination, azimuth, roll angles, and combinations thereof.

12. The method of claim 1, wherein the function approximating agent is selected from the group consisting of neural networks, Gaussian processes, polynomials, and combinations thereof.

13. The method of claim 1, wherein the drilling attitude model is selected from the group consisting of a kinematic model, a dynamical system model, a finite element model, a Markov decision process, and combinations thereof.
